(19) United States
(12) Patent Application Publication
(10) Pub. No.: US 2008/0222493 A1
(43) Pub. Date: Sep. 11, 2008

(54) METHOD AND SYSTEM FOR CONTROL LOOP RESPONSE TIME OPTIMIZATION

(75) Inventors: Nikolai Fediakine, Mountain View, CA (US); Shinkyo Kaku, San Jose, CA (US); Vitali Tikhonov, Mountain View, CA (US)

Correspondence Address: ARENT FOX LLP, 1050 CONNECTICUT AVENUE, N.W., SUITE 400, WASHINGTON, DC, 20036, US

(73) Assignee: ALLIED TELESIS, INC., San Jose, CA (US)

(21) Appl. No.: 12/125,276

(22) Filed: May 22, 2008

Related U.S. Application Data
(63) Continuation-in-part of application No. 11/522,515, filed on Sep. 18, 2006.
(60) Provisional application No. 60/717,194, filed on Sep. 16, 2005.

(51) Int. Cl. H03M 13/00

(52) U.S. Cl. 714/774

(57) ABSTRACT

A method and system for optimizing a response time of a monitoring loop with forward error correction. Characteristics of a fiber optic communications channel are adjusted based on the number of errors corrected in the FEC decoder. An adaptive BER is calculated much faster by using a signal from an FEC decoder, than by comparing input and output transmission. Thereby, the lag time in adjusting the transmission characteristics of the fiber optic channel is minimized and the overall performance of the system is improved.

### CROSS-REFERENCE TO RELATED APPLICATIONS

This application is a continuation-in-part of U.S. application Ser. No. 11/522,515 filed on Sep. 18, 2006, which is based upon and claims the benefit of priority from the prior U.S. Provisional Application No. 60/717,194 filed on Sep. 16, 2005, the entire contents of each of which are incorporated herein by reference.

This application is related to and incorporates in its entirety, U.S. application Ser. No. 11/785,631 filed on Apr. 19, 2007, which is a continuation-in part of U.S. application Ser. No. 11/522,517 filed on Sep. 18, 2006, which is based upon U.S. Provisional Application No. 60/717,193.

### BACKGROUND OF THE INVENTION

1. Field of the Invention

This invention relates to methods and systems for control loop response time optimization. In particular, this invention relates to optimizing the response time of a control loop in a 10 Gigabit-per-second (Gbps) Fiber Communication Channel with Forward Error Correction.

2. Background of the Technology

The advantages of network computing are increasingly evident, as the convenience and efficiency of providing information, communication, or computational power to individuals at their personal computers or other end user devices has led to rapid growth of such network computing, including Internet and intranet systems and applications.

Today's networks carry vast amounts of information. High bandwidth applications supported by these networks include streaming video, audio, and large aggregations of voice traffic. In the future, these bandwidth demands are certain to increase.

Recently, fiber optic communications has emerged as a viable means for transmitting data information over a network. The demand for quick reliable data transmission means continues to increase. Fiber optic communication channels provide means for reliable and efficient transmission of large volumes of data.

As bandwidth requirements increase, correcting errors in data transmission becomes increasingly important. Early methods of error correction, such as handshaking, required prior communication between the transmitting system and the receiving system. This method has many shortcomings, however, especially for systems which are transmitting information from one transmitter to multiple receivers at a time.

Another known method implements a monitoring loop which continuously calculates the Bit Error Rate (BER) and adjusts various system parameters in the attempt to decrease BER. Most communication systems operate with a BER better than about 10⁻¹². 10 Gbps traffic with such a BER has only single errors happening in about 100 seconds of measurement time. Therefore, about 100 seconds of measurement time is required in order to determine the level of error. Once an error is detected, an attempt at reducing BER is made by, first, adjusting a single parameter of a transmitter, then, making another complete measurement of BER. Thus, the next parameter adjustment must wait until after a second complete measurement of BER, i.e. after more than 100 seconds. A drawback to this method is that a response to an increase in the error rate cannot be faster than the measurement time. During the period while new measurements are taking place, the traffic across the media is subject to an increased BER for this extended period of time.

### SUMMARY OF THE INVENTION

There is a need in the art for methods and systems optimizing the response time of a monitoring loop, without the disadvantage of exposing network traffic to an increased BER for extended periods of time. The present invention solves these needs, as well as others, by providing a method and system for optimizing the response time of a control loop in communications channels with forward error correction. Specifically, in one embodiment of the present invention, the characteristics of a fiber optic communications channel which are adjusted based on the number of errors corrected in the Forward Error Correction (FEC) decoder. By determining the BER as a number of corrected errors with respect to an amount of time rather than errors counted in output transmission with respect to an amount of time, the system can determine a quality of signal and direction for adjustment much more quickly. In an implementation using, for example, 10 Gbps traffic with a BER at a level of about 10⁻¹², the number of corrected errors using, is about eight orders of amplitude higher than the number of uncorrected errors. Thus, there is an effective reduction in the necessary measurement time, from about 100 seconds to a millisecond range. The millisecond range is comparable with the round-trip propagation time in 100 km fiber systems.

Adapting the parameters requires a measurement time for measuring error, time for analysis of the measurement, and time to change the parameters. The analysis time is short, for example, on the order of milliseconds. The time to transmit a change in parameters is also minimal, on the order to milliseconds. For example. Thus, if the measurement time can be reduced to the order of milliseconds, it is on level with the analysis and round trip of the parameter change transmission. In the past, it has been the measurement time that set the speed limit for any adaptive algorithm. By making error measurements using the FEC decoder, rather than by comparing input transmission with output transmission, the system according to aspects of the present invention can determine the adaptive BER much faster. This reduces the lag time in making adjustments to the transmission characteristics of the fiber optic channel and improves the overall performance of the system.

Additional advantages and novel features of aspects of the present invention will be set forth in part in the description that follows, and in part will become more apparent to those skilled in the art upon examination of the following or upon learning by practice thereof.

### BRIEF DESCRIPTION OF THE FIGURES

The above and other features and advantages of the present invention will become more apparent to those of ordinary skill in the art by describing in detail exemplary embodiments thereof with reference to the attached drawings in which

FIG. 1 is a generalized scheme of a communication channel utilizing Forward Error Correction (FEC).

FIG. 2 is a high-level diagram of one variation of performance of a monitoring system according to aspects of the present invention.

FIG. 3 is a diagram of another variation of a monitoring system for arbitrary media according to aspects of the present invention.

FIG. 4 is a flowchart showing operation of an implementation of aspects of the present invention.

FIG. 5 is a flowchart showing operation of another implementation of aspects of the present invention.

FIG. 6 is a diagram of aspects of a performance monitoring system, as depicted in connection with FIGS. 2 and 3.

FIG. 7 is a graph showing receiver sensitivity and the relationship between the BER with and without FEC coding.

FIG. 8 presents a computer system implementation capable of carrying out the functionality of and/or being used in connection with aspects of the present invention.

### DETAILED DESCRIPTION

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of elements may be exaggerated for clarity of illustration. Like reference characters refer to like elements throughout.

Under International Telecommunication Union Telecommunication Standardization Sector Standards G.709 (ITU-T G.709) and G.975 (ITU-T G.975), which are incorporated by reference herein in their entirety, certain fiber optic communication channels, for example, a 10GE/OC-192 fiber communication channel, as featured in one embodiment of the present invention, is equipped with FEC, and a system for monitoring the performance of the data transmission.

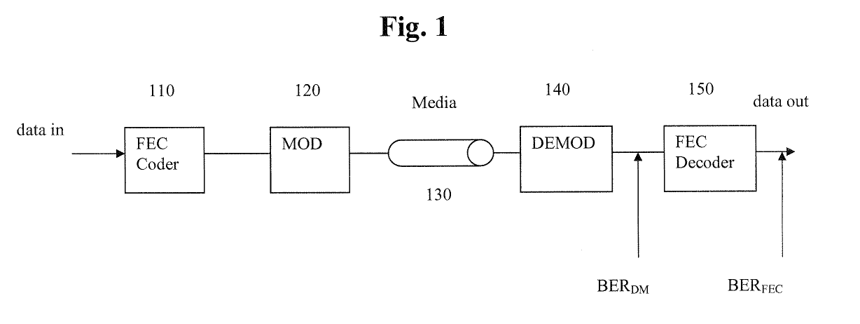

FIG. 1 depicts a communications channel utilizing FEC. In FIG. 1, data is fed into FEC coder 110. The encoded data is then sent to a modulator 120, where the data is transmitted across a media 130. Media 130 may be, for example, a fiber optic cable, another type of cable, or any other type of transmission media. The signal is received at a demodulator 140, and the BER is calculated at the demodulator and is designated by BER_{DM}. The demodulated signal is then sent to the FEC decoder 150, which identifies error count and completes error corrections, giving statistics on correctable (N_{CORR}) and uncorrectable errors (N_{UNCORR}), wherein:

N_{TOT}=N_{CORR}+N_{UNCORR}

where N_{TOT} is the total number of errors in the demodulated signal. By normalizing the number of errors with respect to the number of transmitted bits, the BER can be determined prior to FEC as: BER_{DM}=N_{TOT}/N_{BITS}. The BER, calculated with only uncorrectable errors, is designated by BER_{FEC}, wherein: BER_{FEC}=N_{UNCORR}/N_{BITS}. The FEC decoder 150 then completes the error correction. BER_{FEC} is then calculated at the FEC decoder. BER_{FEC} is ideally multiple orders of magnitude smaller than BER_{DM}. The error-corrected signal is then sent as the data output.

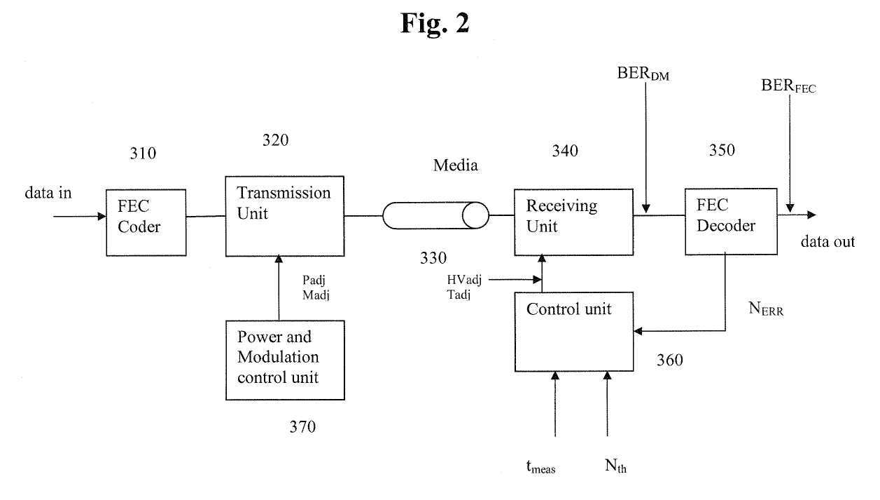

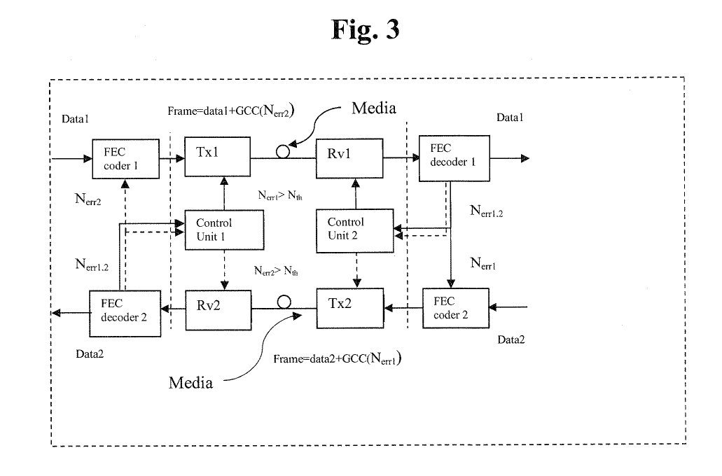

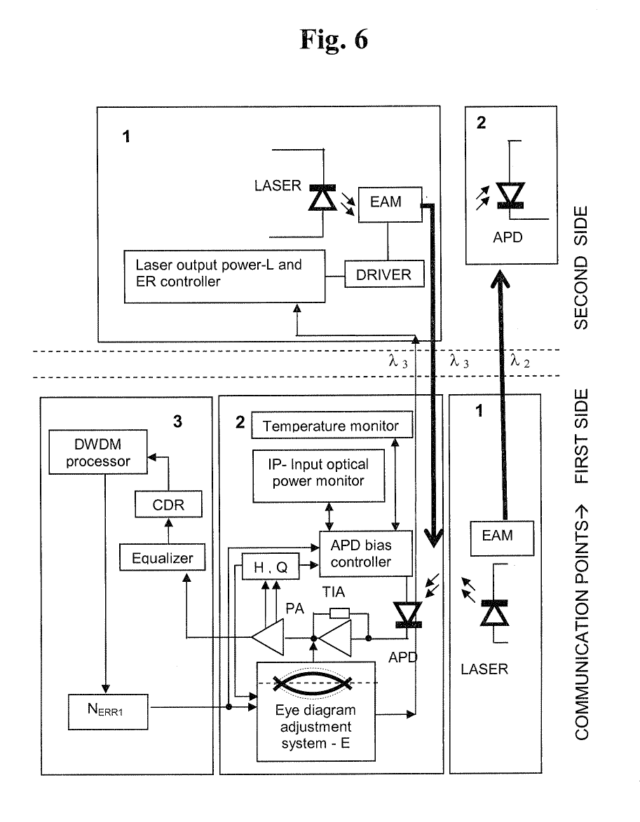

FIG. 2 depicts an exemplary data transmission system 300 according to aspects of the present invention. FEC encoder 310 receives a data stream as input and outputs an encoded data stream. In one embodiment of the present invention, the FEC encoder may be a Reed-Solomon encoder, for example, but any suitable FEC encoding device may be used. A G.975 Reed-Solomon FEC algorithm may be used. The encoded signal is then sent to transmission unit 320. Transmission unit 320, aspects of which are described in more detail in reference to FIG. 6, receives signals P (power), ER (Extinction Ratio), and X (crossing point) from the controller 370. Based on Signals P, ER, and X, transmission unit 320 adjusts optical signal A₁, which is transmitted through a transmission medium 330. The optical signal A₁ is received by the receiving unit 340, aspects of which are described in more detail in reference to FIG. 6. The received signal is then sent to the decoder, which decodes the signal using FEC. The decoder outputs the decoded and error-corrected data stream Data Out, and also outputs the number of errors corrected by the FEC decoder Nₑᵣᵣ to the control unit 360. In one variation shown in FIG. 3, the control unit 360 outputs two electrical signals, HV_{adj} and T_{adj}, which control receiver 340. The receiver may be, for example, an APD receiver. For example, HV_{adj} may adjust the voltage of the receiver and T_{adj} may adjust the temperature. Other signals may be output to receiving unit 340 to adjust other parameters of the receiving unit. The control unit 360 also outputs an optical signal, for example optical signal λ₂, which is sent back across medium 330 to the power and modulation control unit 370. Based on this signal, the power and modulation control unit 370 sends signals to the transmission unit to adjust the power, modulation amplitude, extinction ratio, crossing point, etc. of the transmission unit.

Nₜₕ is the error threshold that is input into the control unit 360. The error threshold may be set by a user or automatically set by a system program.

Information from the control units may be transmitted through in-band General Communications Channel (GCC) as overhead along with the data. The signal will be converted into an optical signal and altered to incorporate overhead with management information. Thus, the original data must be altered. In-band management uses only one optical signal wavelength. Out of band management may be used, as well. With out of band management, a second wavelength is used for the information from the control units. Thus, the signal is converted to a second optical signal wavelength as sent over medium 330 without altering the information to add separate control information. The control unit data is not attached to packet traffic, it travels independently on the second wavelength.

FIG. 3 is a diagram illustrating another variation of a performance monitoring system according to aspects of the present invention. FIG. 3 shows two channels of data traffic performing in a full-duplex mode. As with FIG. 2, the media may be any type of transmission media, for example cable, fiber, etc. FEC Coder 1 performs FEC coding in one direction, and FEC Coder 2 performs FEC coding in the other direction. In addition to FEC coding, FEC Coder 1 and 2 may also frame incoming data and place extra information in the overhead of data transmissions. For example, network management information, including the current quality of data, number of correctable errors Nₑᵣᵣ, and BER, may be transmitted through in-band General Communications Channel (GCC) as overhead, using an elevated data rate after the coder. However, alternative out-band methods can be applied as well, as described above.

Data is sent from the FEC Coder 1 and 2 to transmission units (Tx1 and Tx2), respectively. The transmission units transmit the data over the Media, where it is received by the corresponding receiving unit (Rv1 or Rv2). At the output from the receiving unit Rv1, Rv2, the corresponding FEC Decoder (FEC Decoder 1, FEC Decoder 2) transfer the data (data 1, data 2) to its destination point. If in-band management is being used, the FEC Decoder will also strip the management information off from the frame of the data.

FEC Decoder 1 receives information regarding quality of data 1 traffic as Nₑᵣᵣ. When it is determined that the quality does not meet a predetermined level, a signal is generated to Control Unit 2 to make corrections to parameters for the receiving unit Rv1. At the same time, information regarding the BER (BER 1) is provided to FEC Coder 2, which is sent to FEC Decoder 2. FEC Decoder 2 may then generate signals to Control Unit 1 to make corrections to the parameters of the transmission unit Tx1. Thus, once the upper channel receives BER information that the quality of received data falls below a predetermined level, the upper and bottom channels can simultaneously work to make complementary adjustments of the receiving unit Rv1 on one side of the media and the transmission unit Tx1 on the other side of the media. Similarly, the bottom channel can make adjustments of Rv2 and Tx2 through transmissions over the upper data path. These adjustments may be made simultaneously with the adjustments over the lower data path. For example, for the upper channel, Control Unit 1 adjusts such parameters as the power, modulation, extinction ratio, and crossing point (similar to P_{adj} and M_{adj} in FIG. 2), while Control Unit 2 adjusts parameters such as the voltage level and the temperature (similar to HV_{adj} and T_{adj} in FIG. 2).

As shown in FIG. 3, FEC Decoder 1, 2 calculate whether the correctable number of errors (Nₑᵣᵣ) are greater than a predetermined value (Nₜₕ). FEC Decoder 1 receives Nₑᵣᵣ₂ from the GCC channel and calculates Nₑᵣᵣ₁. For example, if Nₑᵣᵣ₂>Nₜₕ, Control Unit 2 adjusts Tx2, if Nₑᵣᵣ₁>Nₜₕ, Control Unit 2 adjusts Rv1. Control Unit 1 receives the same set of data N_{err1,2}, but when Nₑᵣᵣ₂>Nₜₕ Control Unit 1 adjusts Rv2, and when Nₑᵣᵣ₁>Nₜₕ Control Unit 1 adjusts Tx1.

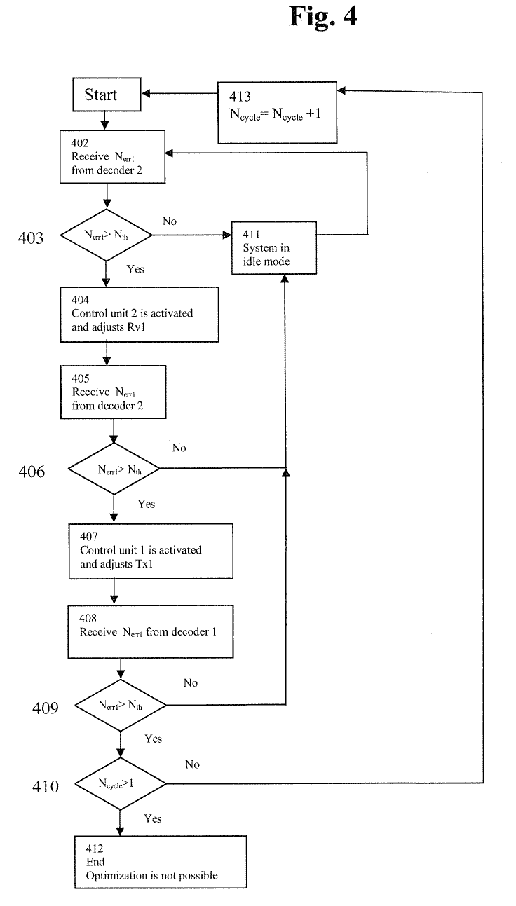

FIG. 4 illustrates an exemplary method implementing aspects of the present invention. At step 402, a number of errors Nₑᵣᵣ₁ is received from decoder 2. At step 403, it is determined whether the number of errors Nₑᵣᵣ₁ is greater than the threshold level of errors Nₜₕ. As noted above, Nₜₕ may be set by a user or set automatically by a system program.

If the number of errors Nₑᵣᵣ₁ is not greater than the threshold level of errors Nₜₕ, then the optimization system remains idle as in step 411, returning to step 402 to receive a new measurement of the number of errors Nₑᵣᵣ₁, until the number of errors Nₑᵣᵣ₁ exceeds the threshold level of errors.

If the number of errors Nₑᵣᵣ₁ is greater than the threshold level of errors Nₜₕ, as shown at step 404, control unit 2, as shown in FIG. 3, is activated and first adjusts the receiver unit Rv1.

At step 405, the number of errors Nₑᵣᵣ₁ is again received from decoder 2, and at step 406, it is again determined if the number of errors Nₑᵣᵣ₁ is greater than the threshold level of errors Nₜₕ. If the number of errors Nₑᵣᵣ₁ is not greater than the threshold level of errors Nₜₕ, then the optimization system becomes idle as in step 411, and returns to step 402 to receive a new measurement of the number of errors Nₑᵣᵣ₁, until the number of errors Nₑᵣᵣ₁ exceeds the threshold level of errors.

If the number of errors Nₑᵣᵣ₁ is still greater than the threshold level of errors Nₜₕ, then control unit 1 is activated in step 407 and makes adjustments to the transmission unit Tx1, as in step 408. At this point, adjustments have been made to both the receiving unit Rv1 and the transmission unit Tx1.

At step 408, the number of errors Nₑᵣᵣ₁ is again received from decoder 2, and at step 409, it is again determined if the number of errors Nₑᵣᵣ₁ is still greater than the threshold level of errors Nₜₕ. If the number of errors Nₑᵣᵣ₁ is not greater than the threshold level of errors Nₜₕ, then the optimization system becomes idle as in step 411, and returns to step 402 to receive a new measurement of the number of errors Nₑᵣᵣ₁, until the number of errors Nₑᵣᵣ₁ exceeds the threshold level of errors.

If the number of errors Nₑᵣᵣ₁ is still greater than the threshold level of errors Nₜₕ, then the system proceeds to step 410, where it is determined if the cycle has been completed more than once. If the cycle has been completed more than once, it is determined that optimization is not possible, as in step 412. If the cycle has not been completed more than once, the system counts the completion of the cycle in step 413 and returns to the start to repeat step 402. At this point, the system sends data using the new parameters for the transmission unit and/or the receiving unit.

The duplex mode system depicted in FIG. 3, allows for parameters to be adjusted simultaneously or complementarily by control unit 1 and control unit 2. For example, the method described in connection with FIG. 4 describes the steps carried out by the system in response to the measure number of errors Nₑᵣᵣ₁ at decoder 2. However, a similar method may be carried out at the same time, or at alternate times for the measured number of errors Nₑᵣᵣ₂ at decoder 1, as described in connection with FIG. 3.

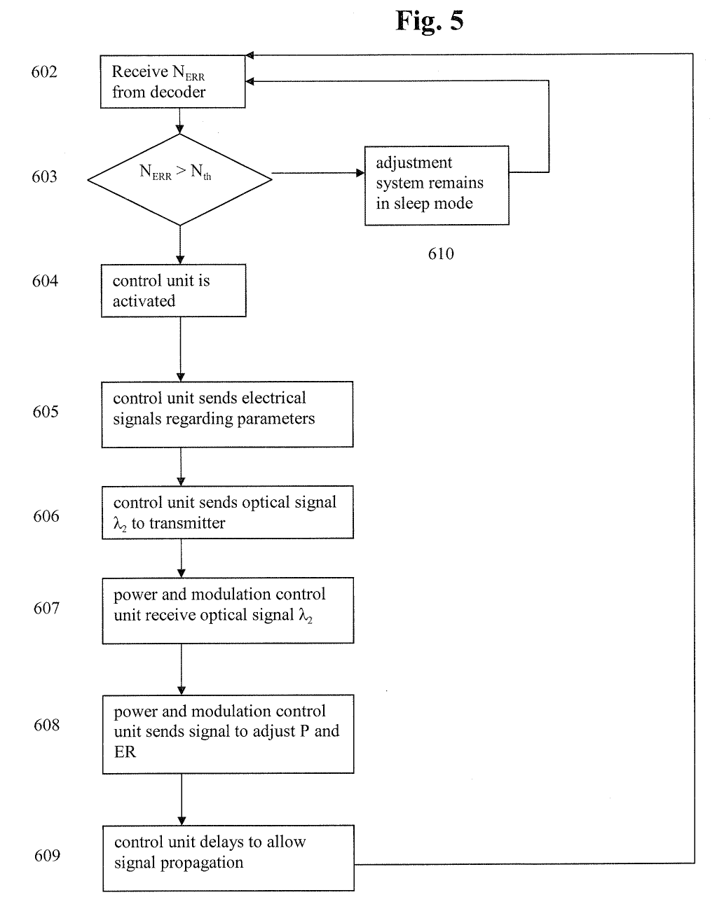

FIG. 5 illustrates another exemplary method according to aspects of the present invention. In step 602, a number of errors is received from a decoder. At step 603, it is determined whether the number of errors N_{ERR} is greater than a threshold level of errors Nₜₕ. If the number of errors N_{ERR} is greater than a threshold level of errors Nₜₕ, then the method proceeds to step 604, where a control unit is activated. If not, then the adjustment system remains in a sleep mode, until it is determined that a measured number of errors exceeds the threshold level of errors.

At step 605, the control unit sends signals regarding the adjustment of certain parameters. These signals may be directed to a receiving unit, and the parameters may include for example, a voltage and temperature parameter.

At step 606, the control unit sends a signal to the transmitter. This signal regards additional parameters at the transmitter that may need adjustment in order to bring the measured number of errors below the threshold level. At step 607, a power and modulation control unit on the transmitter side of the system receive the signal sent by the control unit. At step 608, the power and modulation control unit sends a signal to the transmitter to adjust a parameter. This signal is based on the received transmission from the control unit. The signal may instruct the transmission unit to adjust a parameter such as power, extinction ration, modulation, and crossing point. At step 609, the control unit delays additional adjustments in order to allow a data signal to propagate through the system. At this point, the system begins sending data using the new parameters for the transmission unit and/or the receiving unit. After step 609, the method returns to step 602 and receives a measured number of errors N_{ERR}. The method then moves again through the steps.

FIG. 6 illustrates an exemplary optical network channel that may be used in connection with aspects of the present invention. Aspects of such an optical network as described in more detail in U.S. application Ser. No. 11/785,631 filed on Apr. 19, 2007, the contents of which are incorporated herein by reference.

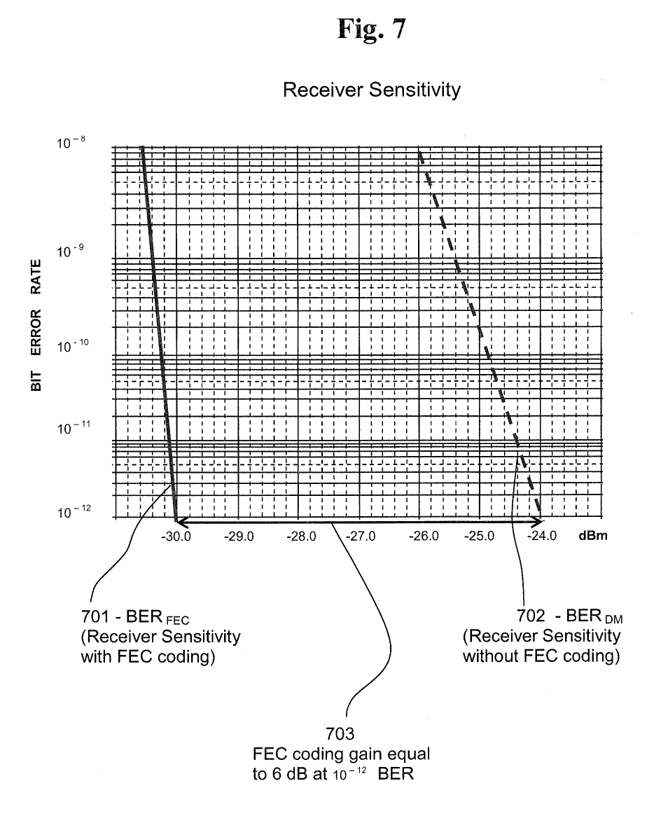

FIG. 7 illustrates the efficiency gain that is provided by aspects of the present invention. This graph shows the Bit Error Rate versus input power (in dBm) for a system using FEC coding (701) according to aspects of the present invention, and for a system without FEC coding (702) according to aspects of the present invention. BER is dependent upon the input power in the system. With a lower power used at the transmission unit, a higher amount of noise and error are found in a received signal. Thus, a better signal is typically achieved by increasing the power of the transmission unit. With previous systems a received signal would have a BER of about 10⁻¹² at about −24.0 dBm. In contrast, a system incorporating aspects of the present invention provides the same level of BER at only −30.0 dBm. Thus, as shown in FIG. 7, there is a gain of approximately 6 dBm at a BER of 10⁻¹². Thus, aspects of the present invention provide a more sensitive receiver, because a desired standard for BER may be achieved using a lower level of power.

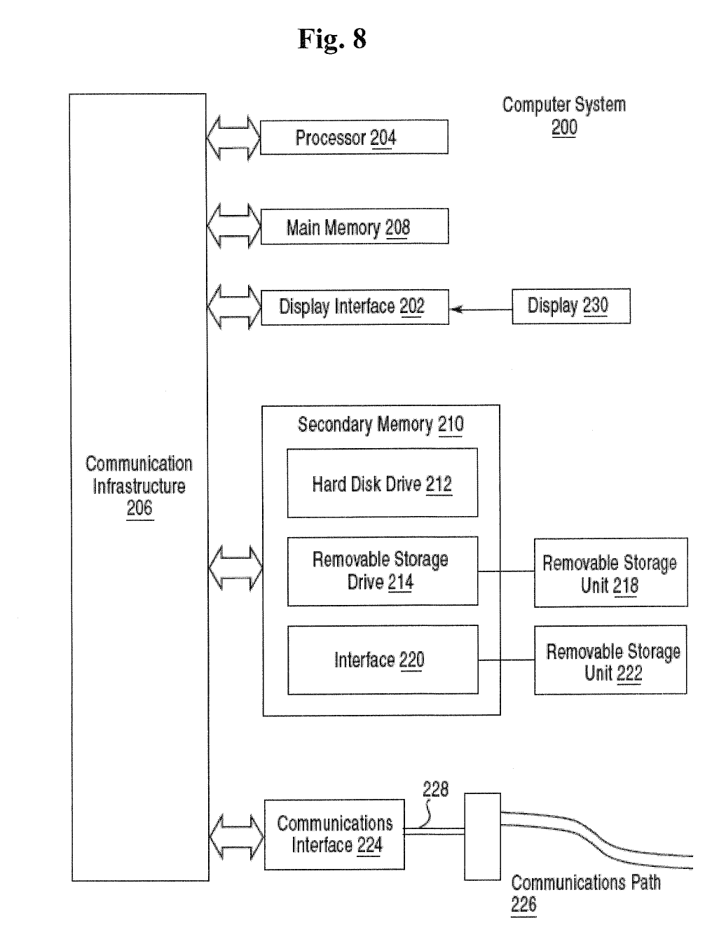

Aspects of the present invention may be used in conjunction with and/or implemented using hardware, software or a combination thereof and may be implemented in one or more computer systems or other processing systems. In one embodiment, the invention is directed toward one or more computer systems capable of carrying out the functionality described herein. An example of such a computer system 200 is shown in FIG. 8.

Computer system 200 includes one or more processors, such as processor 204. The processor 204 is connected to a communication infrastructure 206 (e.g., a communications bus, cross-over bar, or network). Various software embodiments are described in terms of this exemplary computer system. After reading this description, it will become apparent to a person skilled in the relevant art(s) how to implement the invention using other computer systems and/or architectures.

Computer system 200 can include a display interface 202 that forwards graphics, text, and other data from the communication infrastructure 206 (or from a frame buffer not shown) for display on the display unit 230. Computer system 200 also includes a main memory 208, preferably random access memory (RAM), and may also include a secondary memory 210. The secondary memory 210 may include, for example, a hard disk drive 212 and/or a removable storage drive 214, representing a floppy disk drive, a magnetic tape drive, an optical disk drive, etc. The removable storage drive 214 reads from and/or writes to a removable storage unit 218 in a well known manner. Removable storage unit 218, represents a floppy disk, magnetic tape, optical disk, etc., which is read by and written to removable storage drive 214. As will be appreciated, the removable storage unit 218 includes a computer usable storage medium having stored therein computer software and/or data.

In alternative embodiments, secondary memory 210 may include other similar devices for allowing computer programs or other instructions to be loaded into computer system 200. Such devices may include, for example, a removable storage unit 222 and an interface 220. Examples of such may include a program cartridge and cartridge interface (such as that found in video game devices), a removable memory chip (such as an erasable programmable read only memory (EPROM), or programmable read only memory (PROM)) and associated socket, and other removable storage units 222 and interfaces 220, which allow software and data to be transferred from the removable storage unit 222 to computer system 200.

Computer system 200 may also include a communications interface 224. Communications interface 224 allows software and data to be transferred between computer system 200 and external devices. Examples of communications interface 224 may include a modem, a network interface (such as an Ethernet card), a communications port, a Personal Computer Memory Card International Association (PCMCIA) slot and card, etc. Software and data transferred via communications interface 224 are in the form of signals 228, which may be electronic, electromagnetic, optical or other signals capable of being received by communications interface 224. These signals 228 are provided to communications interface 224 via a communications path (e.g., channel) 226. This path 226 carries signals 228 and may be implemented using wire or cable, fiber optics, a telephone line, a cellular link, a radio frequency (RF) link and/or other communications channels. In this document, the terms “computer program medium” and “computer usable medium” are used to refer generally to media such as a removable storage drive 214, a hard disk installed in hard disk drive 212, and signals 228. These computer program products provide software to the computer system 200. The invention is directed to such computer program products.

Computer programs (also referred to as computer control logic) are stored in main memory 208 and/or secondary memory 210. Computer programs may also be received via communications interface 224. Such computer programs, when executed, enable the computer system 200 to perform the features of the present invention, as discussed herein. In particular, the computer programs, when executed, enable the processor 204 to perform the features of the present invention. Accordingly, such computer programs represent controllers of the computer system 200.

In an implementation where aspects of the invention are implemented using software, the software may be stored in a computer program product and loaded into computer system 200 using removable storage drive 214, hard drive 212, or communications interface 224. The control logic (software), when executed by the processor 204, causes the processor 204 to perform the functions of the invention as described herein. In another variation, aspects of the invention are implemented primarily in hardware using, for example, hardware components, such as application specific integrated circuits (ASICs). Implementation of the hardware state machine so as to perform the functions described herein will be apparent to persons skilled in the relevant art(s).

In yet another variation, aspects of the invention may be implemented using a combination of both hardware and software.

Example embodiments of aspects of the present invention have now been described in accordance with the above advantages. It will be appreciated that these examples are merely illustrative of aspects of the present invention. Many variations and modifications will be apparent to those skilled in the art.

What is claimed is:

1. A method for optimizing response time of a control loop, the method comprising:
receiving an encoded data stream at a receiving unit;
correcting errors in the encoded data stream; and
adjusting parameters of the receiving unit based on the number of errors corrected.

2. A method for optimizing response time of a control loop, the method comprising:
encoding a data stream with forward error correction;
transmitting the encoded data stream across a medium using a transmitting unit;
receiving the encoded data stream at a receiving unit;
decoding the data stream and performing error correction; and
adjusting parameters of the transmitting unit and the receiving unit based on the number of errors corrected when decoding the encoded data stream.

3. A system for optimizing response time of a control loop, the system comprising:
a transmitting unit;
a receiving unit;
a control unit for controlling the transmitting unit and the receiving unit; and
an error correcting unit for decoding a data stream and performing error correction;
wherein the control unit adjusts parameters of the transmitting unit and the receiving unit based on a number of errors corrected by the error correcting unit.
